(19) United States
(12) Patent Application Publication
(10) Pub. No.: US 2011/0203841 A1
(43) Pub. Date: Aug. 25, 2011

(54) CONTACT PIN FOR AN ELECTRONIC CIRCUIT

(76) Inventors: Oliver Gradtke, Reutlingen (DE); Walter Roethlingshoefer, Reutlingen (DE)

(21) Appl. No.: 12/995,895

(22) PCT Filed: Apr. 20, 2009
(86) PCT No.: PCT/EP2009/054667

§ 371 Date: Apr. 21, 2011

(30) Foreign Application Priority Data
Jun. 20, 2008 (DE) 10 2008 002 558.5

(51) Int. Cl. H05K 1/11

(52) U.S. Cl. 174/261

(57) ABSTRACT

A contact pin for an electronic circuit is described which has at least one ceramic circuit carrier, the circuit carrier having at least on feedthrough for accommodating the contact pin and the circuit carrier having electrical contact surfaces in the area of the feedthrough for accommodating the contact pin, and the contact pin being only elastically deformed when inserted into the feedthrough. The contact pin may have an electrical contact spring in the form of an insertion stop on the insertion side in addition to or instead of one of the radial bulges, the contact spring being generally designed in the shape of a circular sector and pressing onto the circuit carrier using the outer surface of the circular sector as a stop surface or having a barbed hook on the end which is inserted through the feedthrough in the circuit carrier, the barbed hook preventing the contact pin from sliding back after the contact pin has been inserted through the feedthrough.

### FIELD OF THE INVENTION

The present invention relates to a contact pin for an electronic circuit which has at least one ceramic circuit carrier, the circuit carrier having at least one feedthrough for accommodating the contact pin, and the circuit carrier having electrical contact surfaces in the area of the feedthrough for accommodating the contact pin, and the contact pin being only elastically deformed when inserted into the feedthrough. According to refinements of the present invention, the contact pin may have an electrical contact spring in the form of an insertion stop on the insertion side in addition to or instead of one of the radial bulges, the contact spring being generally designed in the shape of a circular sector and pressing onto the circuit carrier using the outer surface of the circular sector as a stop surface or having a barbed hook on the end which is inserted through the feedthrough in the circuit carrier, the barbed hook preventing the contact pin from sliding back after the contact pin has been inserted through the feedthrough.

### BACKGROUND INFORMATION

In electrical control units, it is frequently necessary to attach so-called contact pins in the p.c. board or the circuit substrate to connect electrical lines on the p.c. board or on the substrate using contact pins that stick out from the substrate, for example to provide plug-in devices or other electrical contacting means. Press-fit pins, which are usually used for this, are pressed into the circuit carrier under relatively high pressure, the diameter of the pin being slightly larger than the diameter of the feedthrough in the circuit carrier or in the circuit substrate, so that the contact pin is firmly clamped in the circuit carrier or the p.c. board after being pressed therein.

A corresponding electronic component having at least one connecting wire is described in German Patent Application No. DE 103 03 009 A1, the connecting wire being designed at one end as a press-fit contact for pressing into a contact opening.

A disadvantage of using press-fit contacts of this type is that the mechanical load acting upon the circuit substrate or the p.c. board is very great, so that methods of this type are unsuitable for ceramic circuit carriers, since ceramic circuit carriers are very brittle, have little deformability and may easily break under such high mechanical loads.

### SUMMARY

An object of the present invention is to provide a contact pin which is suitable for being fastened in a ceramic carrier permanently and in a securely contacted manner without mechanical stresses being exerted on the ceramic circuit carrier material which may cause damage. In accordance with an example embodiment of the present invention, when the contact pin is inserted into a feedthrough in the ceramic circuit carrier, the material of the contact pin is only elastically deformed, while a plastic deformation of the contact pin material is avoided. This may be achieved by designing the dimensions and/or forming the contact zone according to the example embodiment of the present invention.

According to a refinement of the present invention, the contact pin is designed in such a way that it has two radial bulges. Radial bulges in this case are understood to mean that the contact pin has at its bulging point at least one circular bulge which is designed in such a way that one of the circular diameters of the bulge coincides with the longitudinal axis of the contact pin and the circular diameter of the bulge perpendicular to this circular diameter is oriented toward the longitudinal axis of the contact pin in the radial direction and has the largest diameter D. Radial bulges are also understood to mean the provision of a barbed hook and/or a contact element which branches off in a nearly parallel manner in the area of contact with the contact pin and the contact element is bent outward by a circular bend generally perpendicularly to the contact pin axis in the area of the contact surface for the circuit carrier.

It is furthermore advantageous that the radial bulges have a diameter at their thickest point which is greater than the diameter of the feedthrough, and the radial bulge is additionally dimensioned in such a way that the bulge of the contact pin may be pressed through the feedthrough using a predetermined force without causing plastic deformation of the bulge material. The diameter of the radial bulge at its thickest point is greater than the diameter of the feedthrough, so that when this contact pin is pressed into the feedthrough in the circuit carrier, the contact pin fits securely in the circuit carrier and may not easily fall out. The difference between the diameter of the radial bulge and the diameter of the feedthrough may not be too large, since the material of the contact pin would otherwise be plastically deformed when the contact pin is pressed into the feedthrough in the circuit carrier, thus producing a mechanical load on the circuit carrier material, whereby the ceramic circuit carrier might break or crack as a result of its porous material properties. Accordingly, the difference between the diameter of the radial bulge and the diameter of the feedthrough should be only large enough that the material is elastically deformed when it is pressed into the feedthrough, and thus the mechanical force which the radial bulge applies to the ceramic circuit does not become too great.

It is furthermore advantageous if the radial bulges are situated an axial distance apart, the distance being generally equal to or only slightly greater than the thickness of the circuit carrier to be contacted. As a result, the radial bulges are situated at the upper end of the feedthrough as well as at the lower end of the feedthrough after the contact pin has been pressed into the circuit carrier, which prevents the contact pin from sliding back or sliding farther into the feedthrough, since the radial bulges at both ends of the feedthrough prevent a movement of this type.

It is furthermore advantageous if the radial bulges have an generally circular shape and a firm fit of the contact pin in the feedthrough of the circuit carrier is ensured.

It is particularly advantageous that the two radial bulges are designed as two contradirectional, S-shaped contact sections. By designing the two radial bulges as S-shaped contact sections, each half-wave of the S-shaped contact section forms a semicircle which, together with the semicircular section of the second S-shaped contact section, forms a circle, it being possible to press the two semicircles together and form a particularly flexible contact pin, which permits a secure and permanent fit in the feedthrough of the circuit carrier, due to its greater elastic deformability.

It is furthermore advantageous that the contact pin has an electrical contact spring in the form of an insertion stop on the side from which the contact pin is inserted into the feedthrough. This electrical contact spring may be generally designed in the shape of a circular sector, and presses against the circuit carrier using the outer surface of the circular sector as a stop surface. An insertion stop of this type may be designed, for example, in the shape of a circular quadrant, the end of the quadrant sector branching parallel from the contact pin axis, and the other end of the contact spring being positioned generally perpendicular to the contact pin axis, thus achieving a relatively large contact surface of the contact spring on the circuit carrier. In particular, in the event that a contact surface for electrical contacts is provided in addition to the circuit carrier, this design makes it possible for greater currents to be transmitted from the contact pin to the circuit carrier or in the opposite direction. It is advantageous that the electrical contact spring elastically contacts the contact surface of the circuit carrier in the area of the feedthrough when the contact pin is in the engaged state, and the contact pin is prevented from sliding further through the feedthrough even if the radial bulges do not fit precisely in the feedthrough.

The contact spring is advantageously provided in addition to the two radial bulges, so that an additional electrical contact is established over a large surface area by the electrical contact spring to conduct higher currents, or the contact spring may also be provided as an alternative to one of the two radial bulges, so that only the radial bulge is pressed through the feedthrough in the circuit carrier and the contact pin is fixed in place by the contact spring in the upper area of the circuit carrier.

Furthermore, it is advantageous that the contact pin has a barbed hook on the end which is inserted through the feedthrough in the circuit carrier, the barbed hook preventing the contact pin from sliding back through the feedthrough after the contact pin has been inserted. This barbed hook may be attached, for example, at an acute angle to the contact pin axis so that the barbed hook is pressed against the contact pin when the contact pin is inserted through the feedthrough and the barbed hook spreads out from the contact pin after passing all the way through so that the free end of the barbed hook prevents the contact pin from sliding back through the feedthrough, since the free end of the barbed hook is supported on the underside of the circuit carrier. A contact surface for establishing an electrical contact to the contact pin may also be advantageously provided on the underside of the circuit carrier so that the barbed hook may also produce an electrical contact on the underside, which even further improves the current-carrying capacity of this contact system.

This barbed hook may be provided in addition to the two radial bulges of the contact pin, so that the mechanical fixing of the contact pin in the circuit carrier is further improved. Furthermore, it is also possible to alternatively design the barbed hook as one of the two radial bulges so that the radial bulge which is pressed all the way through the feedthrough in the circuit carrier may be dispensed with and this radial bulge is formed by the barbed hook.

According to a particularly advantageous design, the contact pin may additionally have a contact spring on the upper side of the circuit carrier and a barbed hook on the underside of the circuit carrier in addition to the two radial bulges, which may have, for example, a disk-shaped design, whereby a particularly good radial fixing of the contact pin in the circuit carrier is achieved due to the fact that the radial bulges prevent a radial clearance of the contact pin, and an axial clearance of the contact pin in the feedthrough is avoided by the contact spring, which acts as an end stop, and by the barbed hook, which is used to prevent the contact pin from sliding back.

According to a further advantageous embodiment, it is also provided that the contact pin, the contact spring, which acts as an insertion stop and electrical contact, and the barbed hook, which is used to prevent the contact pin from sliding back out of the feedthrough, are designed as the two radial bulges, so that this specific embodiment may have a certain radial clearance of the contact pin in the feedthrough, while an axial clearance is kept within narrow limits due to the contact spring and the barbed hook, thereby making it possible to permanently ensure an elastic contact between the contact pin and the circuit carrier.

Further features, applications and advantages of the present invention are derived from the following description of exemplary embodiments of the present invention, which are illustrated in the figures of the drawing. All features described or illustrated by themselves or in any combination form the subject of the present invention.

### BRIEF DESCRIPTION OF THE DRAWINGS

Exemplary embodiments of the present invention are explained below on the basis of the figures.

FIG. 1a shows a three-dimensional view of a specific embodiment of the contact pin and the feedthrough in the circuit carrier.

FIG. 1b shows a sectional representation of the contact pin according to FIG. 1a in the pressed-in state.

FIG. 2a shows a side view of a specific embodiment, in which the radial bulges are designed as two contradirectional, S-shaped contact sections.

FIG. 2b shows a three-dimensional representation of the specific embodiment according to FIG. 2a.

FIG. 2c shows a sectional representation of the contact pin according to FIGS. 2a and 2b in the pressed-in state.

FIG. 3a shows a side view of the contact pin according to the present invention, which additionally has a contact spring.

FIG. 3b shows a three-dimensional view of the contact pin according to the present invention, including the contact spring.

FIG. 3c shows a sectional representation of the contact pin according to the present invention, including the contact spring, in the pressed-in state.

FIG. 4a shows a side view of a further specific embodiment of the contact pin according to the present invention, in which the two radial bulges are designed as an electrical contact spring and as a barbed hook.

FIG. 4b shows a three-dimensional representation of the contact pin according to the present invention as shown in FIG. 4a.

FIG. 4c shows a sectional representation of the contact pin according to FIGS. 4a and 4b in the pressed-in state.

### DETAILED DESCRIPTION OF EXAMPLE EMBODIMENTS

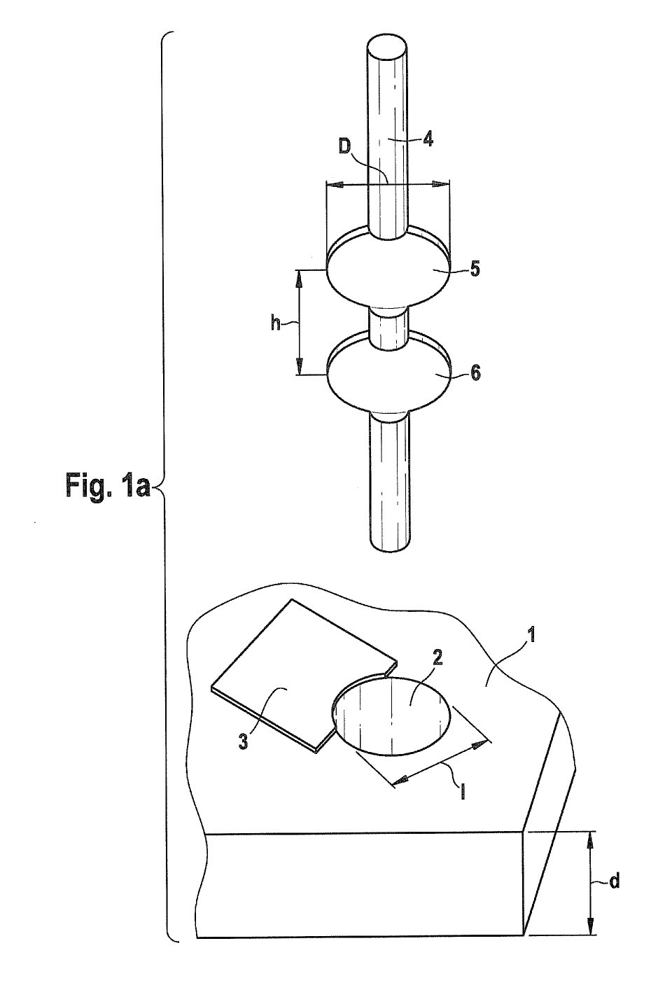

FIG. 1a shows a circuit carrier 1, which was manufactured, in particular, from a porous material, for example from a ceramic material. To establish electrical connections between circuit carrier 1 and other components, contact pins are usually pressed into circuit carrier 1. FIG. 1a also illustrates a contact pin 4 of this type which has two radial bulges 5, 6, the contact pin 4 being inserted into a feedthrough 2 in circuit carrier 1. Feedthrough 2 in electrical circuit carrier 1 has a diameter I as well as an electrical contact surface 3, which is limited by the edge of feedthrough 2. Contact pin 4, which is pressed into feedthrough 2, has two radial bulges 5, 6, each of these bulges 5, 6 having a maximum diameter D. Radial bulges 5, 6 may be provided with a disk-shaped design, as illustrated, the disk being oriented in such a way that a diameter of the disk coincides with the longitudinal axis of contact pin 4, and the diameter of the disk perpendicular to this diameter is oriented radially to the longitudinal axis of contact pin 4 and forms maximum diameter D of the radial bulge. Maximum diameter D of radial bulges 5, 6 is dimensioned in such a way that it is slightly larger than diameter I of feedthrough 2 so that, when contact pin 4 is pressed into ceramic circuit carrier 1, the material of radial bulges 5, 6 is elastically deformed, and contact pin 4 is permanently anchored in feedthrough 2. Distance h between the two radial bulges 5, 6 is dimensioned in such a way that it corresponds approximately to thickness d of circuit carrier 1, it being possible for axial distance h to be slightly larger than thickness d of circuit carrier 1, so that, in the pressed-in state, the two thickest points of radial bulges 5, 6 are slightly outside the area of circuit carrier 1.

FIG. 1b shows a sectional representation of the device according to an example embodiment of the present invention, circuit carrier 1, having feedthrough 2, again being illustrated. An electrical contact surface 3, via which contact pin 4 forms an electrical connection, is provided on the upper side of electrical circuit carrier 1. Contact pin 4 was pressed through feedthrough 2, so that the widest point of lower radial bulge 6 extends halfway out of the lower outlet opening of feedthrough 2, while upper radial bulge 5 on the upper side of the circuit carrier also extends halfway out. Due to the dimensioning of maximum diameter D of radial bulges 5, 6, which are only slightly larger than diameter I of feedthrough 2, the material of radial bulge 6 deforms only elastically, so that contact pin 4 is clamped into feedthrough 2 and only a slight mechanical load acts upon the porous and brittle material of circuit carrier 1. Clamping radial bulges 5, 6 in the edge areas of feedthrough 2 further ensures a reliable electrical contacting of contact surface 3, which may also extend into feedthrough 2 according to an advantageous refinement.

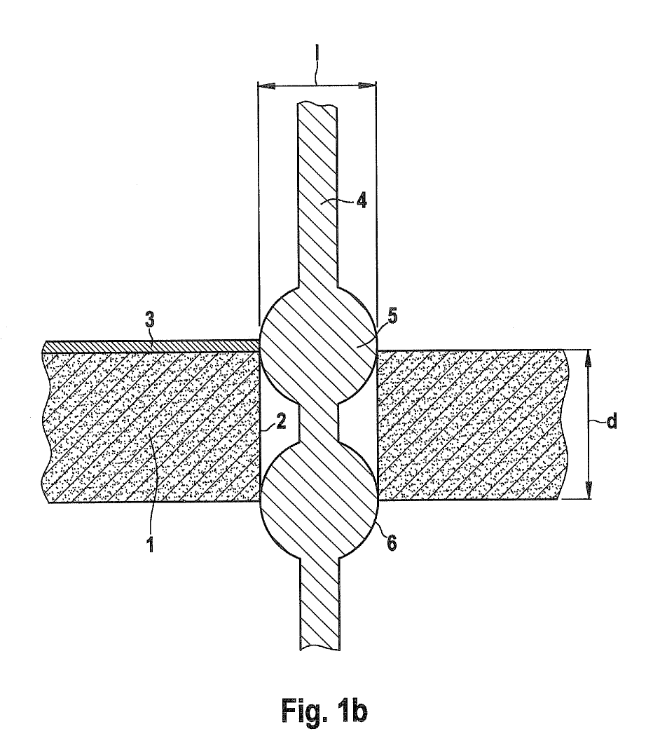

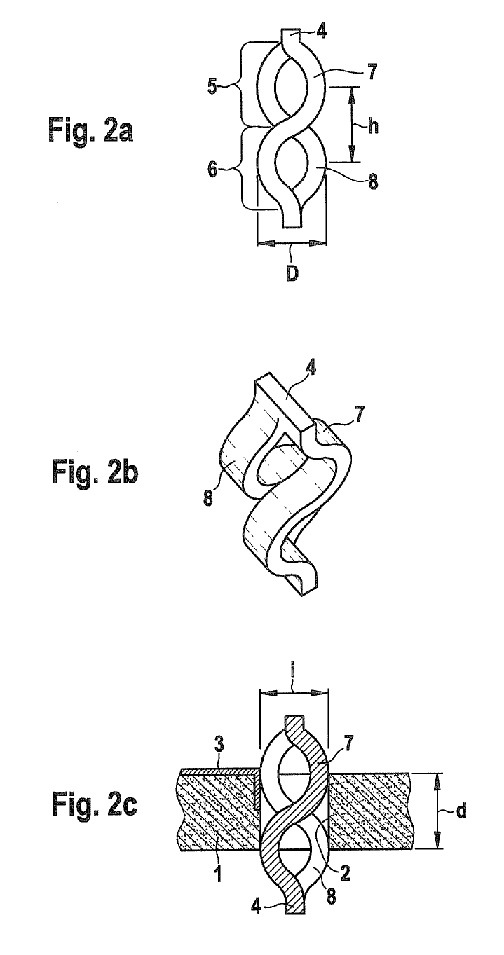

FIG. 2a shows a further specific embodiment of the device according to the present invention, contact pin 4 in this case having two radial bulges 5, 6 which include two contradirectional, S-shaped waves 7, 8. Contact pin 4 has a divided and wave-shaped design along its longitudinal axis, so that first radial bulge 5 is formed by the first two half-waves of parts 7 and 8, and second radial bulge 6 is formed by the two second half-waves of S-shaped waves 7, 8. This results in two radial bulges 5, 6, which are designed to be elastic in relation to each other and thus have a particularly large elastic deformation area for the purpose of pressing them into feedthrough 2 in a circuit carrier 1. The two S-shaped, contradirectional wave sections 7 and 8 are formed in such a way that they again have diameter D at the two thickest points, diameter D being adapted to diameter I of feedthrough 2. Furthermore, the two wave-shaped sections 7, 8 of contact pin 4 are bent in such a way that the two thickest points of radial bulges 5, 6 have a distance h, which was also adapted to thickness d of circuit carrier 1.

FIG. 2b shows a three-dimensional representation of the device according to the present invention illustrated in FIG. 2a, the two contradirectional, S-shaped wave segments 7, 8 again being illustrated which may be further continued in one piece as contact pin 4 above the two radial bulges 5, 6 as well as below the two radial bulges 5, 6. In the area of intersection between the two wave-shaped sections 7, 8, the two parts are not connected to each other, so that both radial bulges become elastically compressed in the radial direction, and contact pin 4 may be pressed into a feedthrough 2 in an electrical circuit 1.

As an alternative to the design having contradirectional, S-shaped wave sections 7, 8, which are continued in one piece as contact pin 4 above the two radial bulges 5, 6 as well as below the two radial bulges 5, 6, it is possible to design contact pin 4 in such a way that contradirectional, S-shaped wave sections 7, 8 of contact pin 4 are continued in two pieces below the two radial bulges 5, 6, whereby the two lower ends of contact pin 4 are deflected transversally while and after contact pin 4 is pressed into feedthrough 2, thereby making it possible to achieve particularly low elastic forces acting upon circuit carrier 7, 8.

FIG. 2c shows a built-in state of this type, circuit carrier 1 once again being illustrated as having feedthrough 2, an electrical contact surface 3 which continues into feedthrough 2 being illustrated on the upper side of circuit carrier 1. Circuit carrier 1 has a thickness d as well as a feedthrough 2 having diameter I, into which contact spring 4 was pressed. The two radial bulges 5, 6 compress when pressed in, due to the fact that the two wave-shaped sections 7, 8 expand in length and become clamped in feedthrough 2 in the radial direction in the pressed-in state. The force which is applied by the two S-shaped wave sections to the edge of feedthrough 2 in circuit carrier 1 is dimensioned in such a way that mechanical damage to porous circuit carrier material 1 is avoided, while contact pin 4 is unable to slide out of feedthrough 2. This is achieved in that contact pin 4 undergoes only an elastic deformation via its bulge areas 5, 6, while plastic deformation of the material does not occur.

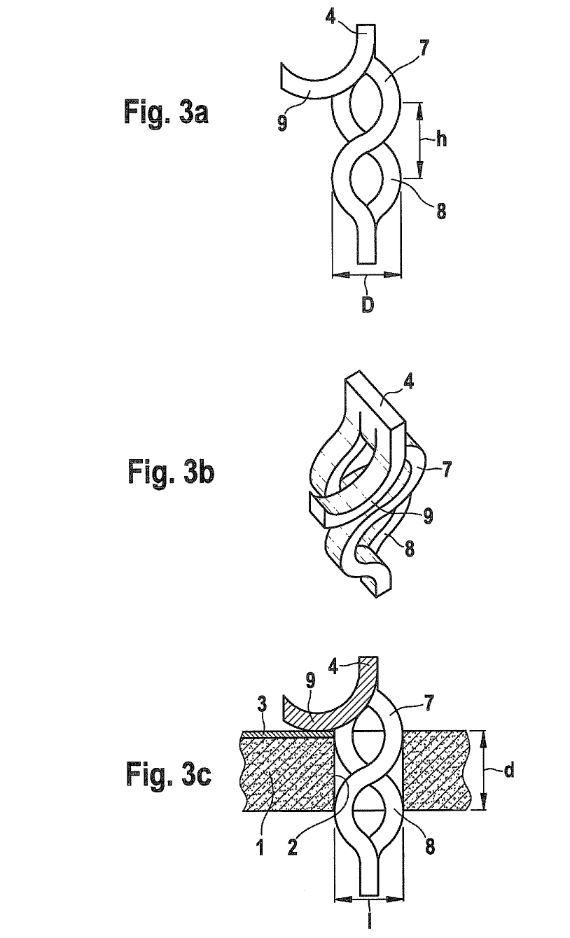

FIG. 3a shows an advantageous refinement of the specific embodiment according to the present invention as illustrated in FIGS. 2a through 2c. It is apparent that contact pin 4 again has two contradirectional, S-shaped waves 7, 8 in the area of its press-in zone, the waves being elastically compressible in their diameter D. According to FIG. 3a, a contact spring 9 is additionally attached which simultaneously acts as an insertion stop for contact pin 4. This contact element 9 is generally designed in the shape of a circular quadrant, so that, when contact pin 4 is pressed into feedthrough 2 of circuit carrier 1, the outer surface of contact spring 9 lies on the upper side of circuit carrier 1 via the area approximately perpendicular to the contact pin axis and touches contact surface 3 so that, on the one hand, an excessively deep pressing of contact pin 4 into feedthrough 2 is avoided and, on the other hand, a large contact area of contact spring 9 on contact surface 3 is established, which significantly increases the current-carrying capacity of this contact pin 4.

FIG. 3b shows the specific embodiment according to FIG. 3a as a three-dimensional view, this corresponding generally to the device according to the present invention from FIG. 2b and to which insertion stop 9, which may act as an electrical contact spring, has been added.

FIG. 3c shows a sectional model of pressed-in contact pin 4 according to FIG. 3a, p.c. board 1, including feedthrough 2, again being illustrated and having a p.c. board thickness d. On the upper side of p.c. board 1, the figure again shows contact surface 3, which may be designed, for example, as a metal plating layer, on which insertion stop 9 lies when contact pin 4 is in the pressed-in state and presses against contact surface 3 under a certain elastic force and thus establishes secure electrical contacting. The clamping of the two contradirectional, S-shaped contact zones 7, 8 in feedthrough 2 generally corresponds to the illustration in FIG. 2c.

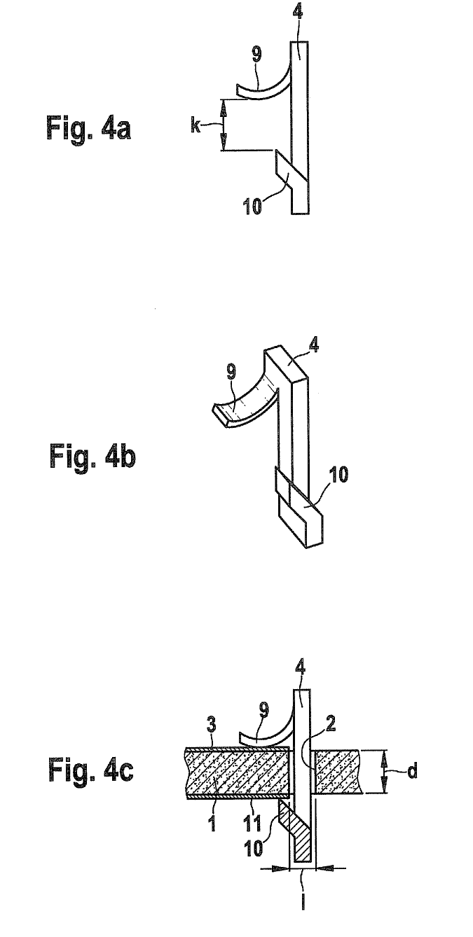

FIG. 4a shows a side view of a further particularly advantageous embodiment of the device according to the present invention, in which contact pin 4 is again illustrated, having an electrical contact spring 9 which corresponds to the designs in FIG. 3. Deviating from the designs according to FIG. 3, upper radial bulge 5 is designed only as contact spring 9, and lower radial bulge 6 is designed as barbed hook 10. Barbed hook 10 is designed here in such a way that it forms an acute angle with the longitudinal access of contact pin 4 and, when contact pin 4 is pressed in, it is deformed parallel to the contact pin axis and spreads open into its original shape after passing through feedthrough 2 in circuit carrier 1, preventing contact pin 4 from being retracted through feedthrough 2. In the specific embodiments according to FIGS. 1 through 3, distance h between the two radial bulges 5, 6 is dimensioned in such a way that it is slightly greater than thickness d of p.c. board 1. In the exemplary embodiment according to FIG. 4, axial distance k of the two radial bulges 9, 10 is divergently dimensioned to be slightly less than thickness d of p.c. board 1, making it possible to ensure secure and reliable contacting. FIG. 4b shows a three-dimensional representation of contact pin 4 according to FIG. 4a; contact spring 9 and barbed hook 10 may be designed as bent sheet metal parts. In FIG. 4c, contact pin 4 is again fastened in feedthrough 2 of circuit carrier 1, which is, in particular, a ceramic circuit carrier, contact pin 4 being pressed in by pressing it through feedthrough 2 against the elastic pressure of contact spring 9 until barbed hook 10 has passed all the way through the feedthrough, so that it may spread open. If contact pin 4 is released after barbed hook 10 has spread open, contact pin 4 is retracted by the elastic force of contact spring 9 until contact pin 4 is fixed in the axial direction by an equilibrium of forces being established in the axial direction of contact pin 4, the elastic force of contact spring 9 pressing contact pin 4 upward, on the one hand, and pressing contact pin 4 downward, on the other hand, along its axial direction, due to barbed hook 10, which also has elastically resilient properties. To establish this equilibrium of forces, distance k between upper radial bulge 5, which is designed as contact spring 9, and lower radial bulge 6, which is designed as barbed hook 10, must be dimensioned to be smaller than thickness d of p.c. board 1, since contact pin 4 otherwise has too large an axial clearance and is unable to ensure electrical contacting of contact surface 3 or contact surface 11.

According to the specific embodiment described according to FIG. 4, a further advantage results from the fact that both a contact surface on the upper side and a contact surface on the underside may establish an electrical connection with contact pin 4, which may further increase the current-carrying capacity of this connecting system. However, a disadvantage of the exemplary embodiment according to FIG. 4 is that contact pin 4 has a radial clearance within feedthrough 2 which is not possible according to the specific embodiments illustrated in FIGS. 1 through 3. For this reason, it is also provided according to the present invention that the specific embodiments having disk-shaped bulges, as illustrated in FIG. 1, or having contradirectional, S-shaped wave sections 7, 8 according to FIGS. 2 and 3, be combined with the specific embodiment according to FIG. 4, it being possible to provide a contact spring 9 and a barbed hook 10 in addition to the two radial bulges 5, 6 or 7, 8.

1-15. (canceled)

16. A contact pin for an electronic circuit which has at least one ceramic circuit carrier, the circuit carrier having at least one feedthrough for accommodating the contact pin and the circuit carrier having at least one electrical contact surface in an area of the feedthrough for accommodating the contact pin, wherein the contact pin is configured so that it is only elastically deformed when inserted into the feedthrough.

17. The contact pin as recited in claim 16, wherein the contact pin includes two radial bulges

18. The contact pin as recited in claim 17, wherein the radial bulges have a diameter at a thickest point which is greater than a diameter of the feedthrough and is additionally dimensioned in such a way that the bulge of the contact pin may be pressed through the feedthrough using a predetermined force without causing plastic deformation of material of the bulge.

19. The contact pin as recited in claim 17, wherein the radial bulges are situated at an axial distance from each other, which generally corresponds to a thickness of the circuit carrier to be contacted.

20. The contact pin as recited in claim 17, wherein the radial bulges have a generally disk-shaped design.

21. The contact pin as recited in claim 17, wherein the two radial bulges are designed as two contradirectional, S-shaped contact sections.

22. The contact pin as recited in claim 16, wherein the contact pin has an electrical contact spring as an insertion stop on a side from which the contact pin is inserted into the feedthrough, the contact spring being designed generally in a shape of a circular sector and pressing onto the circuit carrier by an outer surface of the circular sector as a stop surface.

23. The contact pin as recited in claim 22, wherein the electrical contact spring elastically contacts the contact surface of the circuit carrier in an area of the feedthrough when the contact pin is in an engaged state.

24. The contact pin as recited in claim 22, wherein the contact pin includes two radial bulges.

25. The contact pin as recited in claim 24, wherein the contact spring is designed as one of the two radial bulges.

26. The contact pin as recited in claim 16, wherein the contact pin has a barbed hook on an end which is inserted through the feedthrough in the circuit carrier, the barbed hook preventing the contact pin from sliding back after the contact pin has been inserted into the feedthrough.

27. The contact pin as recited in claim 26, wherein the contact pin includes two radial bulges.

28. The contact pin as recited in claim 27, wherein the barbed hook is one of the two radial bulges.

29. The contact pin as recited in claim 16, wherein the contact pin includes a contact spring, a barbed hook and two radial bulges.

30. The contact pin as recited in claim 29, wherein a first of the radial bulges is the contact spring and the second of the radial bulges is the barbed hook.
